(19) United States
(12) Patent Application Publication
(10) Pub. No.: US 2010/0264408 A1
(43) Pub. Date: Oct. 21, 2010

(54) Organic Thin Film Transistors, Active Matrix Organic Optical Devices and Methods of Making the Same

(75) Inventors: Mark Bale, Wells (GB); Michael Hatcher, Suffolk (GB)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: CAMBRIDGE DISPLAY TECHNOLOGY LTD., Cambridgeshire (GB)

(21) Appl. No.: 12/743,469

(22) PCT Filed: Nov. 18, 2008
(86) PCT No.: PCT/GB2008/003870

§ 371 Date: Jun. 29, 2010

(30) Foreign Application Priority Data
Nov. 20, 2007 (GB) 0722750.7

(51) Int. Cl. H01L 51/10; H01L 51/40; H01L 33/00

(52) U.S. Cl. 257/40; 438/99; 438/34; 257/E33.044; 257/E51.004

(57) ABSTRACT

A method of manufacturing an organic thin film transistor, comprising: providing a substrate comprising source and drain electrodes defining a channel region; forming a patterned layer of insulting material defining a well surrounding the channel region; depositing a protective layer in the well; subjecting exposed portions of the patterned layer of insulating material to a de-wetting treatment to lower the wettability of the exposed portions; removing the protective layer; and depositing organic semiconductive material from solution into the well.

### FIELD OF INVENTION

The present invention relates to organic thin film transistors active matrix organic optical devices and methods of making the same.

### BACKGROUND OF THE INVENTION

Transistors can be divided into two main types: bipolar junction transistors and field-effect transistors. Both types share a common structure comprising three electrodes with a semi-conductive material disposed there between in a channel region. The three electrodes of a bipolar junction transistor are known as the emitter, collector and base, whereas in a field-effect transistor the three electrodes are known as the source, drain and gate. Bipolar junction transistors may be described as current-operated devices as the current between the emitter and collector is controlled by the current flowing between the base and emitter. In contrast, field-effect transistors may be described as voltage-operated devices as the current flowing between source and drain is controlled by the voltage between the gate and the source.

Transistors can also be classified as P-type and N-type according to whether they comprise semi-conductive material which conducts positive charge carriers (holes) or negative charge carriers (electrons) respectively. The semi-conductive material may be selected according to its ability to accept, conduct, and donate charge. The ability of the semi-conductive material to accept, conduct, and donate holes or electrons can be enhanced by doping the material. The material used for the source and drain electrodes can also be selected according to its ability to accept and injecting holes or electrodes.

For example, a p-type transistor device can be formed by selecting a semi-conductive material which is efficient at accepting, conducting, and donating holes, and selecting a material for the source and drain electrodes which is efficient at injecting and accepting holes from the semi-conductive material. Good energy-level matching of the Fermi-level in the electrodes with the HOMO level of the semi-conductive material can enhance hole injection and acceptance. In contrast, an n-type transistor device can be formed by selecting a semi-conductive material which is efficient at accepting, conducting, and donating electrons, and selecting a material for the source and drain electrodes which is efficient at injecting electrons into, and accepting electrons from, the semi-conductive material. Good energy-level matching of the Fermi-level in the electrodes with the LUMO level of the semi-conductive material can enhance electron injection and acceptance. Ambipolar devices that can function as n or p-type are also known.

Transistors can be formed by depositing the components in thin films to form a thin film transistor (TFT). When an organic material is used as the semi-conductive material in such a device, it is known as an organic thin film transistor (OTFT).

Various arrangements for organic thin film transistors are known. One such device is an insulated gate field-effect transistor which comprises source and drain electrodes with a semi-conductive material disposed there between in a channel region, a gate electrode disposed adjacent the semi-conductive material and a layer of insulting material disposed between the gate electrode and the semi-conductive material in the channel region.

OTFTs may be manufactured by low cost, low temperature methods such as solution processing. Moreover, OTFTs are compatible with flexible plastic substrates, offering the prospect of large-scale manufacture of OTFTs on flexible substrates in a roll-to-roll process.

An example of such an organic thin film transistor is shown in FIG. 1. The illustrated structure may be deposited on a substrate 1 and comprises source and drain electrodes 2, 4 which are spaced apart with a channel region 6 located there between. An organic semiconductor (OSC) 8 is deposited in the channel region 6 and may extend over at least a portion of the source and drain electrodes 2, 4. An insulating layer 10 of dielectric material is deposited over the organic semi-conductor 8 and may extend over at least a portion of the source and drain electrodes 2, 4. Finally, a gate electrode 12 is deposited over the insulating layer 10. The gate electrode 12 is located over the channel region 6 and may extend over at least a portion of the source and drain electrodes 2, 4.

The structure described above is known as a top-gate organic thin film transistor as the gate is located on a top side of the device. Alternatively, it is also known to provide the gate on a bottom side of the device to form a so-called bottom-gate organic thin film transistor.

An example of such a bottom-gate organic thin film transistor is shown in FIG. 2. In order to more clearly show the relationship between the structures illustrated in FIGS. 1 and 2, like reference numerals have been used for corresponding parts. The bottom-gate structure illustrated in FIG. 2 comprises a gate electrode 12 deposited on a substrate 1 with an insulating layer 10 of dielectric material deposited thereover. Source and drain electrodes 2, 4 are deposited over the insulating layer 10 of dielectric material. The source and drain electrodes 2, 4 are spaced apart with a channel region 6 located there between over the gate electrode. An organic semiconductor (OSC) 8 is deposited in the channel region 6 and may extend over at least a portion of the source and drain electrodes 2, 4.

One problem with the aforementioned arrangements is how to contain the OSC within the channel region when it is deposited. A solution to this problem is to provide a patterned layer of insulating bank material 14 defining a well in which the OSC 8 can be deposited from solution by, for example, inkjet printing. Such an arrangement is shown in FIGS. 3 and 4 for bottom and top gate organic thin film transistor respectively. Again, in order to more clearly show the relationship between the structures illustrated in FIGS. 1 and 2, with those illustrated in FIGS. 3 and 4, like reference numerals have been used for corresponding parts.

In particular, the periphery of the well defined by patterned layer of insulating material 14 surrounds some or all of the channel 6 defined between the source and drain electrodes 2, 4 in order to facilitate deposition of the OSC 8, for example, by inkjet printing. Furthermore, as the insulating layer 14 is deposited prior to deposition of the OSC 8, it may be deposited and patterned without damaging the OSC. The structure of the insulating layer 14 can be formed in a reproducible manner using known deposition and patterning techniques such as photolithography of positive or negative resists, wet etching, dry etching, etc.

### SUMMARY OF THE INVENTION

The present applicant has found that even if a patterned layer of well-defining bank material is provided, problems still exist in containing the OSC within the channel region and providing good film formation of the OSC in the channel region using solution processing techniques for deposition of the OSC. Uncontrollable wetting of the well-defining bank material occurs since the contact angle of organic solvents in which the OSC is typically deposited is low. In the worst case the OSC may overspill the well.

In order to solve this problem, the present applicant has found it advantageous to treat the surface of the well-defining bank in order to reduce its wettability prior to depositing the OSC from solution. A de-wetting surface on the top of the well-defining bank layer aids in containing the OSC within the well when it is deposited.

Such a treatment may be performed before patterning the insulating layer or after patterning the insulating layer to define wells. However, the present applicant has found that there are some problems associated with both these possibilities. Treatments to reduce the wettability of the insulating layer are generally unstable and the treated surface tends to revert to its original wettability over a period of time, particularly if subjected to further processing steps. Thus, if the insulating layer is treated in order to reduce its surface wettability prior to patterning to form the well, by the time the well has been formed and the OSC is ready to be deposited, the surface tends to have reverted towards its original wettability. Alternatively, if the well is formed first and then a surface treatment is applied, such surface treatments have been found to damage the active layers of the OTFT exposed in the well. It has been found that in bottom gate devices, the dielectric layer which is exposed when the well is formed is particularly sensitive to de-wetting treatments. Furthermore, for both top and bottom gate devices, source and drain electrodes will be exposed after well formation and the de-wetting treatments can detrimentally affect the contact formed between these electrodes and a subsequently deposited OSC. In fact, for both top and bottom gate devices, it has been found that the channel region of an OTFT is sensitive to de-wetting treatments and, if possible, it would be advantageous to avoid exposure of the channel region to such a treatment.

In light of the above, in accordance with a particularly preferred embodiment of the present invention there is provided a method of manufacturing an organic thin film transistor, comprising: providing a substrate comprising source and drain electrodes defining a channel region; forming a patterned layer of insulting material defining a well surrounding the channel region; depositing a protective layer in the well; subjecting exposed portions of the patterned layer of insulating material to a de-wetting treatment to lower the wettability of the exposed portions; removing the protective layer; and depositing organic semiconductive material from solution into the well.

The advantage of the aforementioned method is that by providing a protective layer in the well, the de-wetting treatment can be performed after well formation while protecting underlying layers in the well.

For bottom gate OTFTs, the providing step comprises depositing a gate electrode, depositing a gate dielectric over the gate electrode, and depositing the source and drain electrodes over the gate dielectric to form the channel region.

For top gate OTFTs, a gate dielectric is deposited over the OSC and a gate electrode is deposited over the gate dielectric.

Preferably, the protective layer is a resist material, most preferably a positive-acting resist. Preferably, the well-defining bank material is also a resist material, but most preferably a negative-acting resist. The protective layer is preferably patterned using the same mask as that used to pattern the well-defining bank layer. By using opposite acting resists for the protective layer and the well-defining bank layer, both layers can be deposited using the same mask and no further mask is needed for the extra lithographic steps involved in forming the protective layer. Of course, it is also possible to achieve the same effect for two positive-acting photoresists (or two negative-acting photoresists) by employing two different masks.

Preferably, the protective layer is patterned such that it covers the entire well floor. The protective layer may also cover the well walls. According to one particularly useful arrangement, the protective layer may be patterned such that it also covers a top portion of the well-defining bank layer around the well.

Methods of removing the protective layer can be solvent-based or aqueous (developed-based) depending on which process gives least modification to the contact angle of the treated well-defining bank layer or is least damaging to the underlying layers in the well.

Preferably, the de-wetting treatment is a plasma treatment such as fluorine containing plasma, e.g. CF₄ plasma.

According to a second aspect of the present invention there is provided an organic thin film transistor manufactured according to the previously described method.

According to other aspects of the present invention there is provided an active matrix organic optical device and method of making the same in which an organic thin film transistor manufactured according to the previously described method is incorporated.

### SUMMARY OF THE DRAWINGS

The present invention will now be described in further detail, by way of example only, with reference to the accompanying drawings in which:

FIG. 1 shows a known top-gate organic thin film transistor arrangement;

FIG. 2 shows a known bottom-gate organic thin film transistor arrangement;

FIG. 3 shows a bottom-gate organic thin film transistor arrangement with a well for containing the organic semiconductor;

FIG. 4 shows a top-gate organic thin film transistor arrangement with a well for containing the organic semiconductor;

FIG. 5 illustrates the method steps involved in forming a bottom-gate organic thin film transistor according to an embodiment of the present invention;

FIG. 6 illustrates the method steps involved in forming a top-gate organic thin film transistor according to an embodiment of the present invention;

FIG. 7 illustrates a portion of an active matrix organic light emitting display comprising an organic thin film transistor and an organic light emitting device; and

FIG. 8 illustrates a portion of another active matrix organic light emitting display arrangement comprising an organic thin film transistor and an organic light emitting device.

### DETAILED DESCRIPTION OF PREFERRED EMBODIMENTS

Embodiments of the present invention introduce an additional resist patterning step into the OTFT process flow to protect the sensitive gate dielectric from damage during the surface treatment of the well-defining bank material prior to OSC deposition. In the preferred embodiments this is done without the need for an additional resist mask. Thus embodiments have the potential for obtaining good OTFT performance whilst retaining optimum printing performance during OSC deposition.

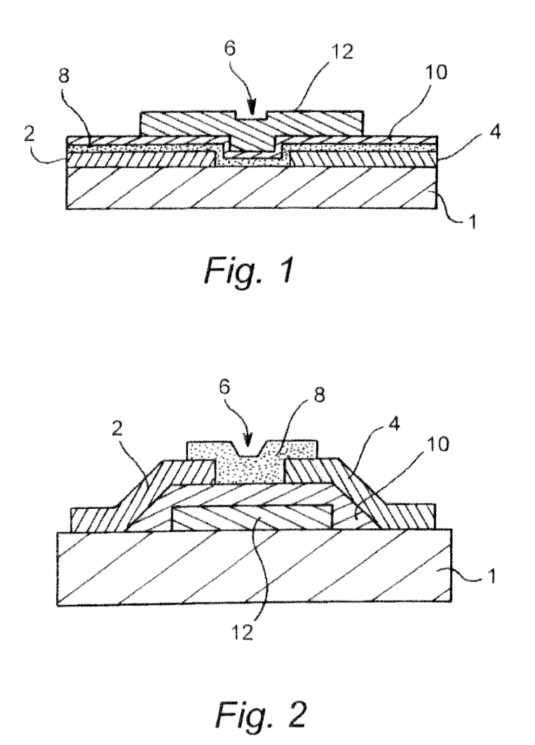

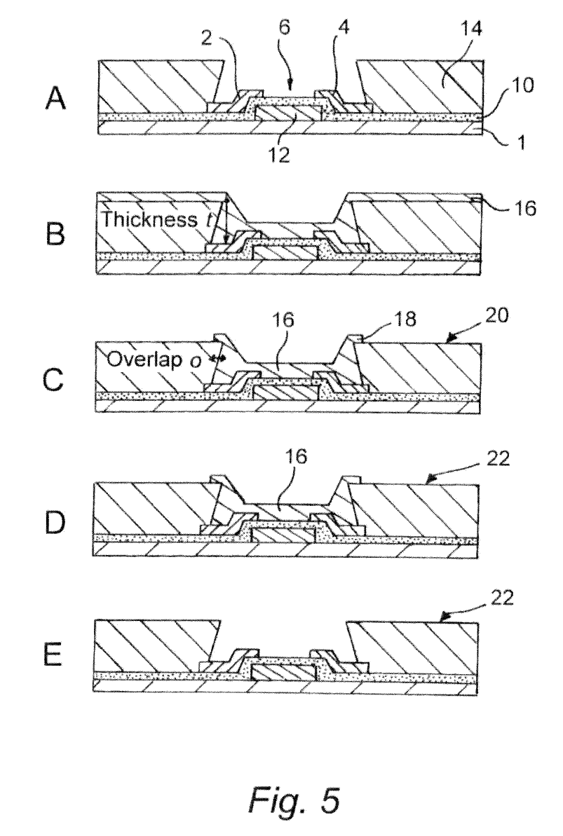

FIG. 5 shows the method steps involved in forming a bottom-gate organic thin film transistor according to an embodiment of the present invention. Like reference numerals to those used in FIGS. 1 to 4 have been used for corresponding parts. FIG. 5(A) depicts the device structure under development prior to OSC deposition. This structure is formed by depositing a gate electrode 12 on a substrate 1, depositing a gate dielectric 10 over the gate electrode 12, depositing source and drain electrodes 2, 4 over the gate dielectric 10 defining a channel region 6 in which the gate dielectric 10 is exposed and forming a patterned layer of insulating bank material 14 defining a well surrounding the channel region 6. In the arrangement illustrated in FIG. 5(A) the well-defining bank 14 has an undercut profile which can be beneficial for forming a good film of OSC when deposited in the well from solution. However, the well-defining bank may alternatively have a positive profile.

It is proposed that in accordance with embodiments of the present invention an OTFT pixel is formed by depositing OSC in the well from solution by, for example, an inkjet printing. In order to obtain controlled behaviour for an OSC solution deposited in this way, it is proposed to prepare the top surface of the well-defining bank layer using a combination of oxygen plasma and CF₄ plasma. The oxygen plasma is used to remove undesirable organic contamination and to create a uniformly wetting surface whereas the CF₄ plasma is used to controllably and preferentially modify the bank surface to make it non-wetting.

Unfortunately these plasma steps have been found to have undesirable effects on OTFT device performance since the exposed layers in the well are sensitive to the plasma steps. For example, the gate dielectric in the TFT channel region forms a crucial interface with the deposited OSC and this interface is detrimentally affected by exposure to the plasma treatments. Other treatments will also affect this sensitive interface. It is also be important for OSC deposition that exposed surfaces in the well retain a level of wettability.

In light of the above, it is proposed herein to use a protective resist layer, defined by an extra lithographic step, to protect the gate dielectric during plasma treatment. The deposition and removal of the extra layer should represent no further risk to device operation since these process steps are the same as the processes already used to pattern preceding substrate layers.

As shown in FIG. 5(B), a protective photoresist layer 16, such as Shipley S1813 or a similar positive-acting novolak resist, is spin-coated onto the substrate. The protective photoresist 16 is patterned using the same mask used to pattern to the well-defining bank layer. Since the well-defining bank layer is formed of a negative-acting material, the mask creates the reverse image of the well and therefore the protective photoresist layer covers the exposed dielectric as shown in FIG. 5(C). By suitable choice of the lithographic processing conditions it should be possible to control to some extent the level of overlap, o, between the two resist features. It may be desirable, for example, to have the additional protective layer cover at least some of the edge 18 of the well-defining bank to ensure full development of the film since the thickness, t, of the protective layer may be larger at the bank edge.

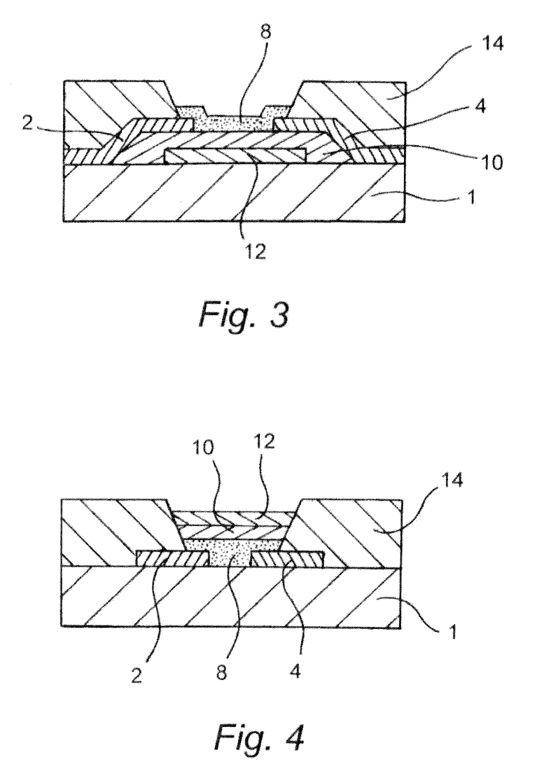

With the gate dielectric protected it is then possible to plasma treat the exposed top-surfaces 20 of the well-defining bank to make non-wetting surfaces 22 as shown in FIG. 5(D). The protective resist 16 is then subsequently removed leaving the non-wetting surfaces 22 on top of the well-defining bank layer as shown in FIG. 5(E). OSC can then be deposited into the well to form a structure as shown in FIG. 3.

Solvent exposure of the bank can result in reduction of the contact angle. For this reason it may be beneficial to over-process the plasma treatment to ensure sufficient contact angle.

Methods of removing the protective resist can be solvent-based or aqueous (developed-based) depending on which process gives least modification to the contact angle of the well-defining bank layer or least damage to the underlying gate dielectric. If developer is used to remove the protective resist, an additional UV exposure is required either directly after the first develop step or after plasma treatment. In either case a sufficient UV dose will have to be used to ensure complete exposure and dissolution of the thickest regions, particularly under the bank undercut. For this reason it may be beneficial for the bank process to be positive in profile.

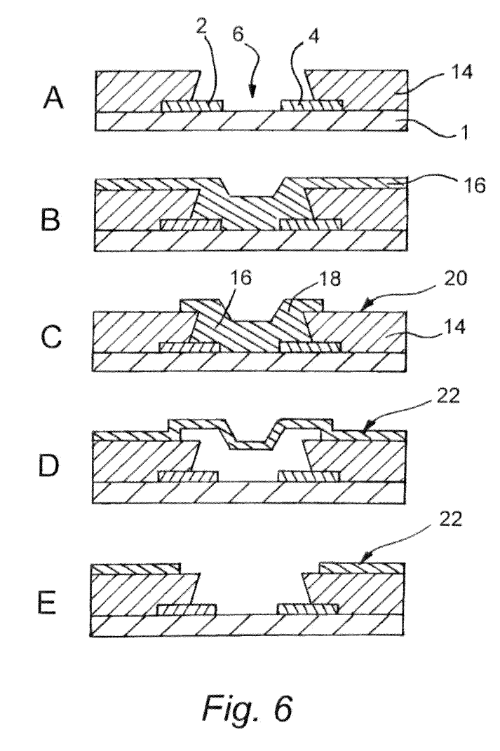

FIG. 6 shows the corresponding method steps involved in forming a top-gate organic thin film transistor according to an embodiment of the present invention. Like reference numerals to those used in FIGS. 1 to 4 have been used for corresponding parts.

The method step are similar to those illustrated in FIG. 5 for the bottom gate arrangement except a different starting structure is used as shown in FIG. 6(A). Here, the substrate 1 is provided with source and drain electrodes 2, 4 defining the channel region 6, with the well-defining bank layer formed over the source and drain electrodes. The protective layer 16 is then deposited as shown in FIG. 6B and patterned as shown in FIG. 6(C) to expose top surfaces 20 of the well-defining bank layer 14. The exposed top-surfaces 20 of the well-defining bank 14 are then plasma treated to make non-wetting surfaces 22 as shown in FIG. 6(D). The protective resist 16 is then subsequently removed leaving the non-wetting surfaces 22 on top of the well-defining bank layer as shown in FIG. 6(E). OSC can then be deposited into the well followed by a gate dielectric and a gate electrode to form a structure as shown in FIG. 4.

Materials and processes suitable for forming an OTFT in accordance with embodiments of the present invention are discussed in further detail below.

### Substrate

The substrate may be rigid or flexible. Rigid substrates may be selected from glass or silicon and flexible substrates may comprise thin glass or plastics such as poly(ethylene-terephthalate) (PET), poly(ethylene-naphthalate) PEN, polycarbonate and polyimide.

The organic semiconductive material may be made solution processable through the use of a suitable solvent. Exemplary solvents include: mono- or poly-alkylbenzenes such as toluene and xylene; tetralin; and chloroform. Preferred solution deposition techniques include spin coating and ink jet printing. Other solution deposition techniques include dip-coating, roll printing and screen printing.

### Organic Semiconductor Materials

Preferred organic semiconductor materials include: small molecules such as optionally substituted pentacene; optionally substituted polymers such as polyarylenes, in particular polyfluorenes and polythiophenes; and oligomers. Blends of materials, including blends of different material types (e.g. a polymer and small molecule blend) may be used.

### Source and Drain Electrodes

For a p-channel OTFT, preferably the source and drain electrodes comprise a high workfunction material, preferably a metal, with a workfunction of greater than 3.5 eV, for example gold, platinum, palladium, molybdenum, tungsten, or chromium. More preferably, the metal has a workfunction in the range of from 4.5 to 5.5 eV. Other suitable compounds, alloys and oxides such as molybdenum trioxide and indium tin oxide may also be used. The source and drain electrodes may be deposited by thermal evaporation and patterned using standard photolithography and lift off techniques as are known in the art.

Alternatively, conductive polymers may be deposited as the source and drain electrodes. An example of such a conductive polymers is poly(ethylene dioxythiophene) (PEDOT) although other conductive polymers are known in the art. Such conductive polymers may be deposited from solution using, for example, spin coating or ink jet printing techniques and other solution deposition techniques discussed above.

For an n-channel OTFT, preferably the source and drain electrodes comprise a material, for example a metal, having a workfunction of less than 3.5 eV such as calcium or barium or a thin layer of metal compound, in particular an oxide or fluoride of an alkali or alkali earth metal for example lithium fluoride, barium fluoride and barium oxide. Alternatively, conductive polymers may be deposited as the source and drain electrodes.

The source and drain electrodes are preferably formed from the same material for ease of manufacture. However, it will be appreciated that the source and drain electrodes may be formed of different materials for optimisation of charge injection and extraction respectively.

The length of the channel defined between the source and drain electrodes may be up to 500 microns, but preferably the length is less than 200 microns, more preferably less than 100 microns, most preferably less than 20 microns.

### Gate Electrode

The gate electrode can be selected from a wide range of conducting materials for example a metal (e.g. gold) or metal compound (e.g. indium tin oxide). Alternatively, conductive polymers may be deposited as the gate electrode. Such conductive polymers may be deposited from solution using, for example, spin coating or ink jet printing techniques and other solution deposition techniques discussed above

Thicknesses of the gate electrode, source and drain electrodes may be in the region of 5-200 nm, although typically 50 nm as measured by Atomic Force Microscopy (AFM), for example.

### Gate Dielectric

The gate dielectric comprises a dielectric material selected from insulating materials having a high resistivity. The dielectric constant, k, of the dielectric is typically around 2-3 although materials with a high value of k are desirable because the capacitance that is achievable for an OTFT is directly proportional to k, and the drain current I_{D} is directly proportional to the capacitance. Thus, in order to achieve high drain currents with low operational voltages, OTFTs with thin dielectric layers in the channel region are preferred.

The dielectric material may be organic or inorganic. Preferred inorganic materials include Si02, SiNx and spin-on-glass (SOG). Preferred organic materials are generally polymers and include insulating polymers such as poly vinylalcohol (PVA), polyvinylpyrrolidine (PVP), acrylates such as polymethylmethacrylate (PMMA) and benzocyclobutanes (BCBs) available from Dow Corning. The insulating layer may be formed from a blend of materials or comprise a multi-layered structure.

The dielectric material may be deposited by thermal evaporation, vacuum processing or lamination techniques as are known in the art. Alternatively, the dielectric material may be deposited from solution using, for example, spin coating or ink jet printing techniques and other solution deposition techniques discussed above.

If the dielectric material is deposited from solution onto the organic semiconductor, it should not result in dissolution of the organic semiconductor. Likewise, the dielectric material should not be dissolved if the organic semiconductor is deposited onto it from solution. Techniques to avoid such dissolution include: use of orthogonal solvents, i.e. use of a solvent for deposition of the uppermost layer that does not dissolve the underlying layer; and crosslinking of the underlying layer.

The thickness of the gate dielectric layer is preferably less than 2 micrometres, more preferably less than 500 nm.

### Further Layers

Other layers may be included in the device architecture. For example, a self assembled monolayer (SAM) may be deposited on the gate, source or drain electrodes, substrate, insulating layer and organic semiconductor material to promote crystallity, reduce contact resistance, repair surface characteristics and promote adhesion where required. In particular, the dielectric surface in the channel region may be provided with a monolayer comprising a binding region and an organic region to improve device performance, e.g. by improving the organic semiconductor's morphology (in particular polymer alignment and crystallinity) and covering charge traps, in particular for a high k dielectric surface. Exemplary materials for such a monolayer include chloro- or alkoxy-silanes with long alkyl chains, e.g. octadecyltrichlorosilane. Similarly, the source and drain electrodes may be provided with a SAM to improve the contact between the organic semiconductor and the electrodes. For example, gold SD electrodes may be provided with a SAM comprising a thiol binding group and a group for improving the contact which may be a group having a high dipole moment; a dopant; or a conjugated moiety.

### OTFT Applications

OTFTs according to embodiments of the present invention have a wide range of possible applications. One such application is to drive pixels in an optical device, preferably an organic optical device. Examples of such optical devices include photoresponsive devices, in particular photodetectors, and light-emissive devices, in particular organic light emitting devices. OTFTs are particularly suited for use with active matrix organic light emitting devices, e.g. for use in display applications.

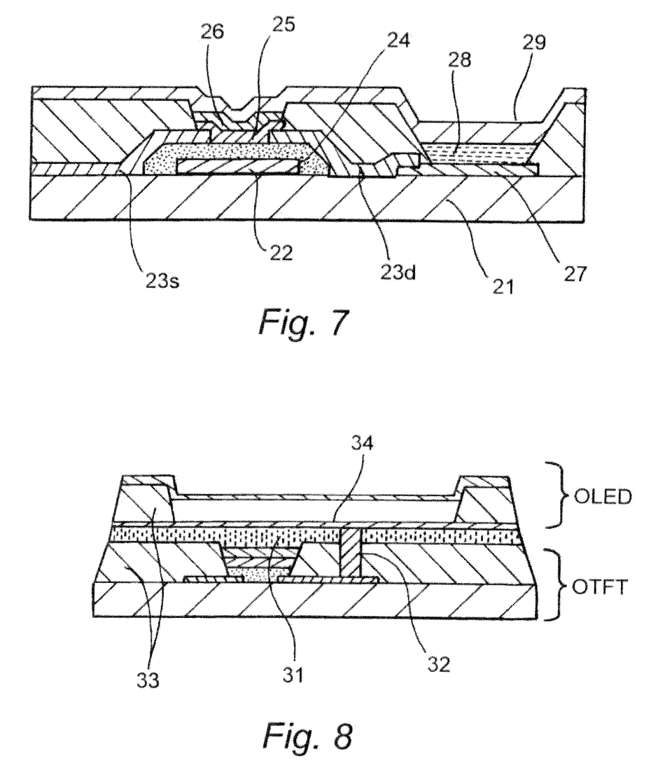

FIG. 7 shows a pixel comprising an organic thin film transistor and an adjacent organic light emitting device fabricated on a common substrate 21. The OTFT comprises gate electrode 22, dielectric layer 24, source and drain electrodes 23s and 23d respectively, and OSC layer 25. The OLED comprises anode 27, cathode 29 and an electroluminescent layer 28 provided between the anode and cathode. Further layers may be located between the anode and cathode, such as charge transporting, charge injecting or charge blocking layers. In the embodiment of FIG. 7, the layer of cathode material extends across both the OTFT and the OLED, and an insulating layer 26 is provided to electrically isolate the cathode layer 29 from the OSC layer 25. In this embodiment, the drain electrode 23d is directly connected to the anode of the organic light emitting device for switching the organic light emitting device between emitting and non-emitting states.

The active areas of the OTFT and the OLED are defined by a common bank material formed by depositing a layer of photoresist on substrate 21 and patterning it to define OTFT and OLED areas on the substrate. In accordance with an embodiment of the present invention the wells defining both the OTFT and the OLED can be protected with a protective layer during manufacture in a manner analogous to that described in relation to FIGS. 5 and 6 prior to deposition of OSC and organic electroluminescent material therein. The common bank material can then be treated to form non-wetting surfaces on a top surface thereof and the protective material removed. The remaining layers of the OTFT and OLED can then be deposited in the wells, the non-wetting surfaces preventing deposited solutions of OSC and organic electroluminescent material from spilling out of their respective wells. According to another embodiment only the OTFT is protected. It has been found that some treatments only damage the OTFT and not the OLED. As such, for some treatments only the OTFT needs to be protected.

In an alternative arrangement illustrated in FIG. 8, an organic thin film transistor may be fabricated in a stacked relationship to an organic light emitting device. In such an embodiment, the organic thin film transistor is built up as described above in either a top or bottom gate configuration. As with the embodiment of FIG. 7, the active areas of the OTFT and OLED are defined by a patterned layer of photoresist 33, however in this stacked arrangement, there are two separate bank layers 33—one for the OLED and one for the OTFT. In accordance with an embodiment of the present invention these two separate bank layers can be protected and treated in an analogous manner to that described in relation to FIGS. 5, 6 and 7 during manufacture. As stated previously, for some treatments only the OTFT needs to be protected and not the OLED.

A planarisation layer 31 (also known as a passivation layer) is deposited over the OTFT. Exemplary passivation layers include BCBs and parylenes. An organic light emitting device is fabricated over the passivation layer. The anode 34 of the organic light emitting device is electrically connected to the drain electrode of the organic thin film transistor by a conductive via 32 passing through passivation layer 31 and bank layer 33.

It will be appreciated that pixel circuits comprising an OTFT and an optically active area (e.g. light emitting or light sensing area) may comprise further elements. In particular, the OLED pixel circuits of FIGS. 7 and 8 will typically comprise least one further transistor in addition to the driving transistor shown, and at least one capacitor.

It will be appreciated that the organic light emitting devices described herein may be top or bottom-emitting devices. That is, the devices may emit light through either the anode or cathode side of the device. In a transparent device, both the anode and cathode are transparent. It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium.

Transparent cathodes are particularly advantageous for active matrix devices because emission through a transparent anode in such devices may be at least partially blocked by OTFT drive circuitry located underneath the emissive pixels as can be seen from the embodiment illustrated in FIG. 8.

While this invention has been particularly shown and described with reference to preferred embodiments thereof, it will be understood by those skilled in the art that various changes in form and detail may be made therein without departing from the scope of the invention as defined by the appended claims.

1. A method of manufacturing an organic thin film transistor, comprising:
providing a substrate comprising source and drain electrodes defining a channel region; forming a patterned layer of insulating material defining a well surrounding the channel region, the well having a floor and walls;
depositing a protective layer in the well;
subjecting exposed portions of the patterned layer of insulating material to a de-wetting treatment to lower the wettability of the exposed portions;
removing the protective layer; and
depositing organic semiconductive material from solution into the well.

2. A method according to claim 1, wherein providing a substrate comprises depositing a gate electrode, depositing a gate dielectric over the gate electrode, and depositing the source and drain electrodes over the gate dielectric to form the channel region.

3. A method according to claim 1, comprising depositing a gate dielectric is over the OSC and depositing a gate electrode over the gate dielectric.

4. A method according to claim 1, wherein the protective layer is a resist material.

5. A method according to claim 4, wherein the protective layer is a positive-acting resist.

6. A method according to claim 1, wherein the patterned layer of insulating material is a resist material.

7. A method according to claim 6, wherein the patterned layer of insulating material is a positive-acting resist.

8. A method according to claim 1, comprising patterning the protective layer using the same mask as that used to pattern the patterned layer of insulating material.

9. A method according to claim 1, comprising patterning the protective layer such that the patterned protective layer covers the entire well floor.

10. A method according to claim 9, comprising patterning the protective layer such that the patterned protective layer further covers at least a portion of the well walls.

11. A method according to claim 10, comprising patterning the protective layer such that the patterned protective layer further covers a top edge portion of the patterned layer of insulating material around the well.

12. A method according to claim 1, comprising removing the protective layer using a solvent-based or aqueous develop-based technique.

13. A method according to claim 1, wherein the de-wetting treatment is a plasma treatment.

14. A method according to claim 13, wherein the plasma treatment comprises a fluorine-based plasma treatment.

15. A method according to claim 14, wherein the fluorine-based plasma treatment uses a CF₄ plasma.

16. A method according to claim 3, wherein the plasma treatment comprises an oxygen plasma treatment.

17. A method of manufacturing an active matrix organic optical device comprising:
forming, on a substrate comprising a patterned electrode layer, at least one bank layer defining a plurality of wells;
depositing a protective layer in the wells;
subjecting exposed portions of the at least one bank layer of insulating material to a de-wetting treatment to lower the wettability of the exposed portions;
removing the protective layer; and
depositing organic semiconductive material into some of the wells from solution to form organic thin film transistors therein and organic optically active material into others of the wells to form light emissive pixels therein.

18. A method according to claim 17, wherein forming at least one bank layer comprises forming a common bank layer provided for both the organic thin film transistors and the pixels on a common substrate, wherein depositing the protective layer comprises depositing the protective layer simultaneously in both the wells for the organic thin film transistors and the wells for the pixels, and wherein subjecting exposed portions of the at least one bank layer of insulating material to a de-wetting treatment comprises simultaneously exposing portions of the common bank layer around both the welts for the organic thin film transistors and the wells for the pixels.

19. An organic thin film transistor, comprising:
a substrate comprising source and drain electrodes defining a channel region;
a patterned layer of insulating material defining a well surrounding the channel region; and
organic semiconductive material disposed in the channel region in the well,
wherein top portions of the patterned layer of insulating material have a de-wetting surface disposed thereon.

20. An organic thin film transistor according to claim 19, wherein the de-wetting surface comprises a fluorinated material.

21. An organic thin film transistor according to claim 20, wherein the fluorinated material comprises CF₄.

22. An active matrix organic optical device comprising a plurality of organic thin film transistors and a plurality of pixels, wherein at least one bank layer is provided for the organic thin film transistors and the pixels, the at least one bank layer defining a plurality of wells, wherein some of the wells contain organic semiconducting material of the organic thin film transistors therein and others of the wells contain organic optically active material of the pixels therein, and wherein top portions of the at least one bank layer have a de-wetting surface disposed thereon.

23. An active matrix organic optical device according to claim 22, wherein the plurality of organic thin film transistors and the plurality of pixels are disposed on a common substrate, wherein the at least one bank layer is a common bank layer provided for both the organic thin film transistors and the pixels, the common bank layer defining the plurality of wells, wherein the common bank layer has the de-wetting surface disposed thereon surrounding both the wells containing the organic semiconducting material of the organic thin film transistors and the wells containing the organic optically active material of the pixels.
